(19) United States
(12) Patent Application Publication
(10) Pub. No.: US 2024/0222492 A1
(43) Pub. Date: Jul. 4, 2024

(54) METHOD FOR PRODUCING A VERTICAL POWER SEMICONDUCTOR COMPONENT, AND VERTICAL POWER SEMICONDUCTOR COMPONENT

(71) Applicant: Robert Bosch GmbH, Stuttgart (DE)

(72) Inventors: Jens Baringhaus, Sindelfingen (DE); Christian Huber, Ludwigsburg (DE)

(21) Appl. No.: 18/557,210

(22) PCT Filed: Apr. 25, 2022
(86) PCT No.: PCT/EP2022/060795

§ 371 Date: Nov. 29, 2023

(30) Foreign Application Priority Data
Apr. 29, 2021 (DE) 10 2021 204 298.8

(51) Int. Cl. H01L 29/78; H01L 21/04; H01L 21/225; H01L 21/304; H01L 21/683; H01L 29/66

(52) U.S. Cl. CPC H01L 29/7802; H01L 21/0485; H01L 21/2253; H01L 21/304; H01L 21/6835; H01L 29/66712

(57) ABSTRACT

A method for producing vertical power semiconductor components. The method includes: applying a first side of a silicon wafer onto a subcarrier wafer, wherein a front side of the vertical power semiconductor components is arranged on the first side of the silicon wafer and the front side of the vertical power semiconductor components comprises a buffer layer and a drift layer; grinding the silicon wafer to a specific thickness; dry etching the silicon wafer; etching the buffer layer; implanting ions into the drift layer, wherein a contact semiconductor layer is formed; generating an ohmic contact by applying a metal layer onto the contact semiconductor layer; and removing the subcarrier wafer.

### FIELD

The present invention relates to a method for producing a vertical power semiconductor component and to a vertical power semiconductor component.

### BACKGROUND INFORMATION

For producing cost-effective vertical power semiconductor components on the basis of gallium nitride, heteroepitaxially deposited gallium-nitride layers are arranged on a silicon wafer. In order to ensure vertical current flow, the silicon wafer must be removed after processing the front side of the vertical power semiconductor component.

An object of the present invention is to ensure complete removal of the silicon wafer.

### SUMMARY

A method according to an example embodiment of the present invention for producing vertical power semiconductor components includes applying a first side of a silicon wafer onto a subcarrier wafer, wherein a front side of the vertical power semiconductor components is arranged on the first side of the silicon wafer and the front side of the vertical power semiconductor components comprises a buffer layer and a drift layer. Furthermore, the method comprises grinding the silicon wafer to a specific thickness; dry etching the silicon wafer; and etching the buffer layer. The method comprises implanting ions into the drift layer, wherein a contact semiconductor layer is formed; generating an ohmic contact by applying a metal layer onto the contact semiconductor layer; and removing the subcarrier wafer.

An advantage here is that the silicon wafer is removed completely.

In one development of the present invention, the ion implantation has a dopant concentration greater than 1e19 cm\hat{ }−3.

It is advantageous here that the contact semiconductor layer has a low resistance.

In one development of the present invention, the ion implantation comprises silicon-containing dopants.

An advantage here is that the ion implantation is cost-effective.

A method according to an example embodiment of the present invention for producing vertical power semiconductor components comprises applying a first side of a silicon wafer onto a subcarrier wafer, wherein a front side of the vertical power semiconductor components is arranged on the first side of the silicon wafer and the front side of the vertical power semiconductor components comprises a buffer layer and a contact semiconductor layer. The method comprises grinding the silicon wafer to a specific thickness; dry etching the silicon wafer; and etching the buffer layer. Furthermore, the method comprises generating an ohmic contact by applying a metal layer to the contact semiconductor layer; and removing the subcarrier wafer.

An advantage here is that the silicon substrate is completely removed in a simple manner.

In one example embodiment of the present invention, the vertical power semiconductor component comprises gallium nitride or silicon carbide.

In a further example embodiment of the present invention, the subcarrier wafer comprises glass or silicon.

It is advantageous here that, during the processing on the rear side, the subcarrier wafer stabilizes the wafer on which the power semiconductor component is applied, and protects it against wafer breakage, and also protects the front side from contamination.

In one development of the present invention, the buffer layer is etched wet-chemically or by means of a chlorine-based dry-etching process.

An advantage here is that the etching processes are highly selective and self-limitation of the Si etching process is achieved.

In a further embodiment of the present invention, the specific thickness is between 100 μm and 500 μm.

It is advantageous here that a simple dry-etching process can be used.

The vertical power semiconductor component comprises a drift layer. According to an example embodiment of the present invention, ions are implanted in the drift layer and the latter has a dopant concentration greater than 1e19 cm\hat{ }−3.

Further advantages emerge from the following description of exemplary embodiments of the present invention.

### BRIEF DESCRIPTION OF THE DRAWINGS

The present invention is explained below with reference to preferred embodiments and the figures.

FIG. 1 shows a first exemplary embodiment of a method according to the present invention for producing a vertical power semiconductor component,

FIG. 2 shows a second exemplary embodiment of the method according to the present invention for producing a vertical power semiconductor component.

FIG. 3 shows a vertical power semiconductor component, according to an example embodiment.

### DETAILED DESCRIPTION OF EXAMPLE EMBODIMENTS

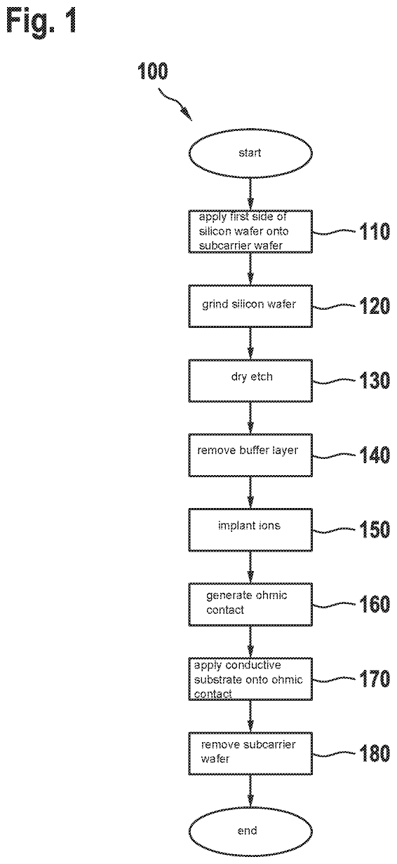

FIG. 1 shows a first exemplary embodiment of a method 100 according to the present invention for producing a vertical power semiconductor component. The method 100 starts with a step 110 in which a first side of a silicon wafer is applied onto a subcarrier wafer, wherein a front side of the vertical power semiconductor component is arranged on the first side of the silicon wafer and the front side of the vertical power semiconductor components comprises a buffer layer and a contact semiconductor layer. At the time of application of the silicon wafer onto the subcarrier wafer, the front side of the vertical power semiconductor components is completed. The silicon wafer is applied onto the subcarrier wafer by means of a temporary, i.e., reversible, bonding process, for example. In a following step 120, the silicon wafer is ground to a specific thickness. The initial thickness of the silicon wafer is generally 1 mm. The specific thickness is in a range between 100 μm and 500 μm.

In a following step 130, the silicon wafer having the specific thickness is dry-etched. The dry-etching process has a high selectivity with respect to the remaining layers of the vertical power semiconductor component, primarily with respect to the buffer layer. Etching takes place with XeF2, for example. Alternatively, instead of dry etching, wet-chemical etching can take place with KOH. In a following step 140, the buffer layer is removed. This removal takes place wet-chemically or by means of a chlorine-based dry-etching process. In a following step 150, ions are implanted in the low-doped drift layer and activated by means of laser annealing, wherein a contact semiconductor layer with a low resistance is formed. In this case, the dopant concentration is greater than 1e19 cm\hat{ }−3. For this purpose, silicon is used, for example. In a following step 160, an ohmic contact is generated on the contact semiconductor layer. This takes place, for example, by applying a metal layer or a metal layer stack onto the contact semiconductor layer and by subsequently laser-annealing. The metal layer or the metal layer stack has a low thickness, for example less than 1 μm. In a following step 170, a conductive substrate is applied onto the ohmic contact. The conductive substrate is, for example, a silicon or metal wafer or a metal foil or a thick galvanic metal layer. In a following step 180, the subcarrier wafer is removed.

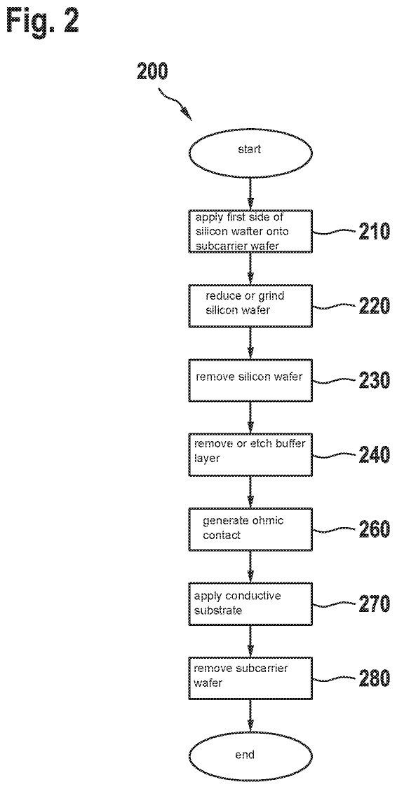

FIG. 2 shows a second exemplary embodiment of a method 200 according to the present invention for producing a power semiconductor component. The method 200 starts with a step 210 in which a first side of a silicon wafer is applied onto a subcarrier wafer, wherein a front side of the vertical power semiconductor components is arranged on the first side and the front side of the vertical power semiconductor components comprises a buffer layer and a contact semiconductor layer. In a following step 220, the silicon wafer is reduced, or ground, to a specific thickness. In a following step 230, the silicon wafer is removed. This takes place by dry etching, for example. In a following step 240, the buffer layer is removed or etched. In a following step 260, an ohmic contact is generated by applying a metal layer onto the contact semiconductor layer. In a following step 270, a conductive substrate is applied onto the ohmic contact. In a following step 280, the subcarrier wafer is removed. In other words, the difference between the first exemplary embodiment and the second exemplary embodiment is that the contact semiconductor layer in the first exemplary embodiment is generated after the complete removal of the silicon wafer. In the second exemplary embodiment, the contact semiconductor layer is generated during the processing of the front side or during the front-end processes. This contact semiconductor layer has grown epitaxially and has a lower dopant concentration for process-related reasons. The resistance of the ohmic contact is therefore higher than in the first exemplary embodiment.

In both exemplary embodiments, the vertical power semiconductor comprises, for example, GaN or SiC. The subcarrier wafer comprises glass or silicon, for example. In steps 120 or 220, the specific thickness of the silicon wafer comprises a range component of between 100 μm and 500 μm. In steps 140 or 240, the buffer layer is removed wet-chemically or by means of an established dry-etching process.

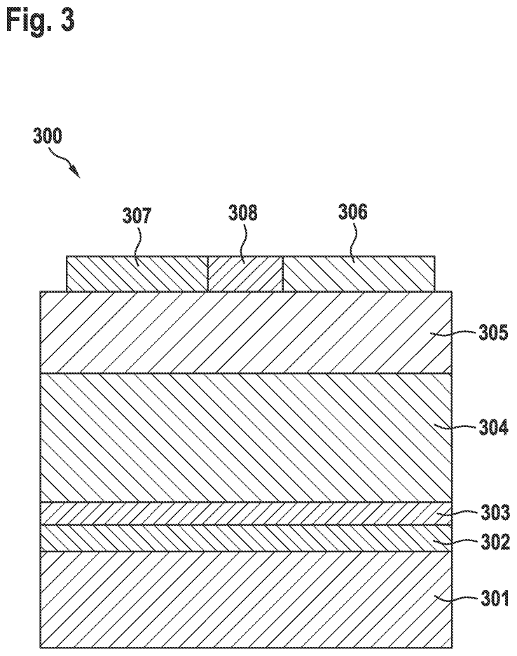

FIG. 3 shows a vertical power semiconductor component 300 according to the present invention in the form of a vertical power transistor. The vertical power transistor comprises a conductive substrate 301. The conductive substrate 301 is, for example, a highly doped silicon substrate connected to a metal layer 302 by means of a bonding process. Alternatively, the conductive substrate 301 comprises a metal wafer, a metal foil or a thick galvanic metal layer. A highly doped contact semiconductor layer 303, which is, for example, n-conductive, is arranged on the metal layer 302. The metal layer 302 and the contact semiconductor layer 303 form an ohmic contact, wherein the metal layer 302 functions as a drain electrode. A low-doped n-conductive drift layer 304 is arranged on the contact semiconductor layer 303. On the drift layer 304 is arranged an active layer 305 or an active region of the vertical power transistor. The active layer in this case comprises a switchable element of the power transistor. A gate terminal 306 and a source terminal 307 are arranged on the active layer 305. The gate terminal 306 and the source terminal 307 are electrically isolated from one another by means of an insulation layer 308.

The vertical power semiconductor component 300 is, for example, designed as a Schottky diode, pn diode, vertical diffusion MOSFET, planar gate MOSFET, trench gate MOSFET, current-aperture vertical electron transistor, vGroove HEMT, or FinFET. Here, the vertical power semiconductor component 300 may also comprise several unit cells of a vertical power transistor.

The vertical power semiconductor component 300 is used in the electric powertrain of electric or hybrid vehicles, for example in the DC/DC converter or inverter, and in vehicle charging devices or inverters for domestic appliances.

1-9. (canceled)

10. A method for producing vertical power semiconductor components, the method comprising the following steps:
applying a first side of a silicon wafer onto a subcarrier wafer, wherein a front side of the vertical power semiconductor components is arranged on the first side of the silicon wafer and the front side of the vertical power semiconductor components includes a buffer layer and a drift layer;
grinding the silicon wafer to a specific thickness;
dry etching the silicon wafer;
etching the buffer layer;
implanting ions into the drift layer, wherein a contact semiconductor layer is formed;
generating an ohmic contact by applying a metal layer onto the contact semiconductor layer; and
removing the subcarrier wafer.

11. The method according to claim 10, wherein the ion implantation has a dopant concentration greater than 1e19 cm\hat{ }−3.

12. The method according to claim 10, wherein the ion implantation includes silicon-containing dopants.

13. A method for producing vertical power semiconductor components, comprising the following steps:
applying a first side of a silicon wafer onto a subcarrier wafer, wherein a front side of the vertical power semiconductor components is arranged on the first side of the silicon wafer and the front side of the vertical power semiconductor components includes a buffer layer and a contact semiconductor layer;
grinding the silicon wafer to a specific thickness;
dry etching the silicon wafer;
etching the buffer layer;
generating an ohmic contact by applying a metal layer onto the contact semiconductor layer; and
removing the subcarrier wafer.

14. The method according to claim 13, wherein the vertical power semiconductor component includes gallium nitride or silicon carbide.

15. The method according to claim 13, wherein the subcarrier wafer includes glass or silicon.

16. The method according to claim 13, wherein the buffer layer is etched wet-chemically or using a chlorine-based dry-etching process.

17. The method according to claim 13, wherein the specific thickness is between 100 m and 500 m.

18. A vertical power semiconductor component, comprising:
a drift layer, wherein ions are implanted in the drift layer and the ions includes a dopant concentration greater than 1e19 cm\hat{ }−3.
